(19) United States
(12) Patent Application Publication
(10) Pub. No.: US 2008/0116461 A1
(43) Pub. Date: May 22, 2008

(54) Semiconductor device and manufacturing method thereof

(75) Inventors: YewChung-Sermon Wu, Padeh City (TW); Chih-Yuan Hou, Padeh City (TW); Chi-Ching Lin, Padeh City (TW); Guo-Ren Hu, Padeh City (TW)

Correspondence Address: BIRCH STEWART KOLASCH & BIRCH, PO BOX 747, FALLS CHURCH, VA, 22040-0747, US

(73) Assignee: CHUNGHWA PICTURE TUBES, LTD

(21) Appl. No.: 11/812,483

(22) Filed: Jun. 19, 2007

(30) Foreign Application Priority Data
Nov. 17, 2006 (TW) 95142666

(51) Int. Cl. H01L 29/06; H01L 21/336

(52) U.S. Cl. 257/66; 438/166; 257/E29.003; 257/E21.412

(57) ABSTRACT

A manufacturing method of a semiconductor device, includes the following steps: providing a substrate with an insulated surface; forming an amorphous silicon layer on the insulated surface; imposing a catalytic metal element on the amorphous silicon layer; heating and catalyzing the amorphous silicon layer to form a poly-silicon layer; forming a diffusion layer and a gettering material layer on the poly-silicon layer in order; proceeding an annealing process on the gettering material layer and the poly-silicon layer to move the residual metal catalyst element from the poly-silicon layer toward the gettering material layer due to the concentration gradient; and removing the diffusion layer and the gettering material layer.

### BACKGROUND OF THE INVENTION

1. Field of the Invention

The present invention relates to a manufacturing method of a semiconductor device, and more especially, to the manufacturing method of a poly-silicon semiconductor device.

2. Background of the Related Art

Semiconductor device formed with low temperature poly-silicon layer has been widely applied to 3 C environment, and especially to the control device of flat display panel (FDP). Comparing the low temperature poly-silicon technology with the amorphous silicon technology, the low temperature poly-silicon technology can be used to make a high resolution and full color FDP because it has a greater electromigration rate, a better structure and electrical characteristics. Besides, using low temperature poly-silicon technology can combine the drive circuits of the panel and form on the glass substrate of FDP directly to reduce the pin connection, and is used to develop and produce the high quality device such as thin film transistor and charge-coupled device (CCD). The general amorphous silicon manufacture process usually uses furnace annealing, rapid thermal annealing and excimer laser annealing. In the process of the furnace annealing, the poly-silicon is deposited on the substrate directly by low pressure chemical vapor deposition under 600° C., but the annealing time is very long during the whole process of nucleation to nucleus growth. The rapid thermal annealing can reduce thermal budget but the crystallization result becomes worse. An excimer laser is used to melt amorphous silicon layer and then the amorphous silicon crystal crystallize during the processes of the excimer laser anneal. But the amorphous silicon crystal is too small due to the lack of rapid condense speed of the melting amorphous silicon.

U.S. Pat. No. 6,197,626 provides a method of forming poly-silicon by using a metal to induce an amorphous silicon layer to crystallize. The method includes the steps of providing an amorphous silicon layer with a metallic surface such as gold or nickel, heating the amorphous silicon layer to form the metal silicide surface and transform the amorphous silicon to the crystal silicon by the atomic movement of the metal silicide, and then forming the poly-silicon layer during annealing. The advantage of the foregoing method is that the poly-silicon can be formed on many types of substrates by using the low temperature manufacturing. But, in the process of the crystallizing an amorphous silicon layer induced by metal, the metal will remain in the lattice of the poly-silicon to form the metal contamination, and that will damage the electrical characteristics of the device. In order to get the poly-silicon layer with higher quality and better electrical characteristics of the device, the metal remnants in the poly-silicon must be reduced. Therefore, this patent also provide another processes, which includes to deposit a SiO₂ and Si₃N₄ layer on the poly-silicon, to form a designed pattern via photolithography process, to implant phosphorus ions, to move the metal remnants in poly-silicon from the non-phosphorus-ion region to the phosphorus-ion region during annealing, and to remove the SiO₂ layer, Si₃N₄ layer and unnecessary poly-silicon layer by using an isotropic etching according to the designed pattern of the device.

However this method spends much time and cost due to the additive photolithography process, three etching processes and a phosphorus ions implant process. Therefore, how to effectively reduce the metal remnants on the prerequisites of decreasing the manufacture time and cost is one of the important demands for manufacturing the semiconductor device.

### SUMMARY OF THE INVENTION

One of objects of this invention is to provide a semiconductor device and a manufacturing method thereof, which forms a diffusion layer to prevent the remnant metal element from flowing back to the semiconductor film.

One of objects of this invention is to provide the semiconductor device and the manufacturing method thereof, which forms an improved diffusion layer for gettering the metal residue and a gettering material layer without using additional photolithography process on the poly-silicon layer to getter the metal residue in the metal-induced poly-silicon layer.

One of objects of this invention is to provide the semiconductor device and the manufacturing method thereof, which makes a poly-silicon layer with bigger crystal and removes residual metal from the poly-silicon layer effectively.

In order to accomplish the above objects, one embodiment of the present invention provides a manufacturing method of a semiconductor device includes the following steps. An amorphous silicon layer is formed on a substrate with an insulated surface; a catalytic metal element is imposed on the amorphous silicon layer to form a poly-silicon layer on the insulated surface by heating and catalyzing the amorphous silicon layer. A diffusion layer and a gettering material layer is subsequently formed on the poly-silicon layer in order. Then, an annealing process is proceeded for the gettering material layer and the poly-silicon layer. Finally, the diffusion layer and the gettering material layer are removed.

### BRIEF DESCRIPTION OF THE DRAWINGS

FIG. 1 is a flow chart illustrating the manufacturing method of the poly-silicon semiconductor device in accordance with an embodiment of the present invention; and

FIG. 2A to FIG. 2E are the cross-sectional diagrams illustrating the process of forming the poly-silicon semiconductor device in accordance with one embodiment of the present invention.

### DETAILED DESCRIPTION OF THE INVENTION

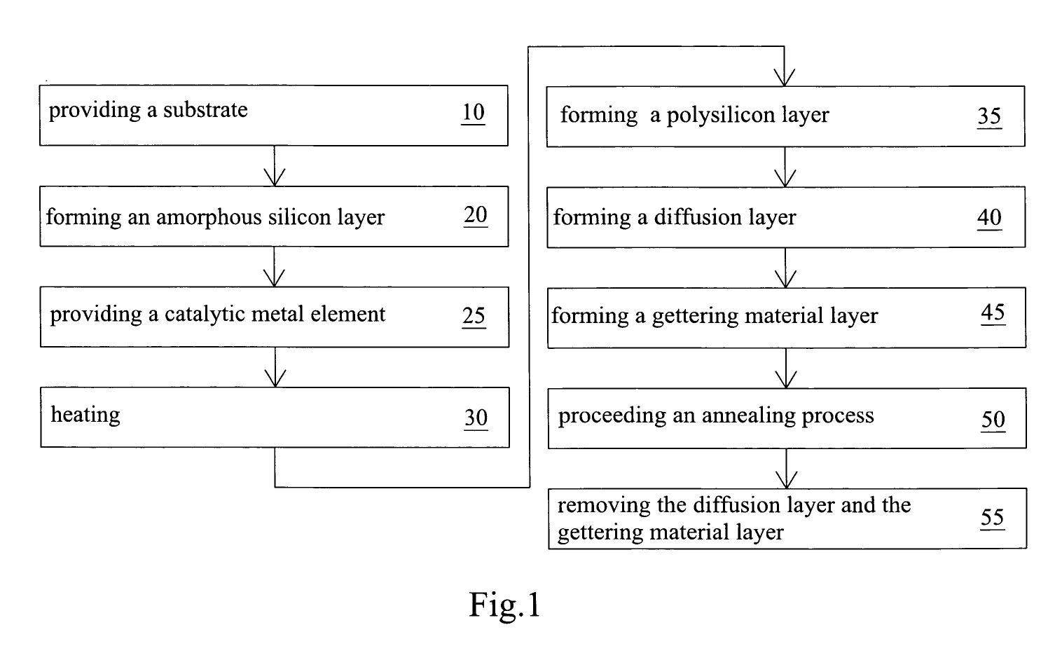

FIG. 1 is a flow chart illustrating the manufacturing method of the poly-silicon semiconductor device in accordance with one embodiment of the present invention. The manufacturing method includes the following steps: a substrate with an insulated surface is provided (step 10); an amorphous silicon layer is formed on the insulated surface (steps 20); a catalytic metal element is imposed on the amorphous silicon layer (step 25); the substrate is heated (step 30); the amorphous silicon layer is catalyzed to form a poly-silicon layer on the insulated surface (step 35); a diffusion layer and a gettering material layer are formed on the poly-silicon layer in order (steps 40, 45), wherein the concentration of the catalytic metal element in the poly-silicon layer is higher than the catalytic metal element in the gettering material layer; an annealing process is proceeded (step 50), wherein, because the concentration of the catalytic metal element in the gettering material layer is lower than the catalytic metal element in the poly-silicon layer, the catalytic metal element is gettered to gettering material layer from the poly-silicon layer; finally, the diffusion layer and the gettering material layer are removed (step 55) so that the residual catalytic metal element in poly-silicon layer is removed accordingly.

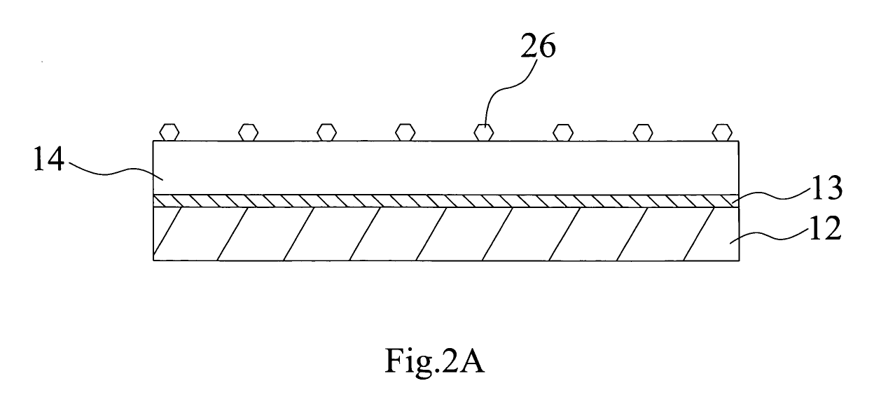

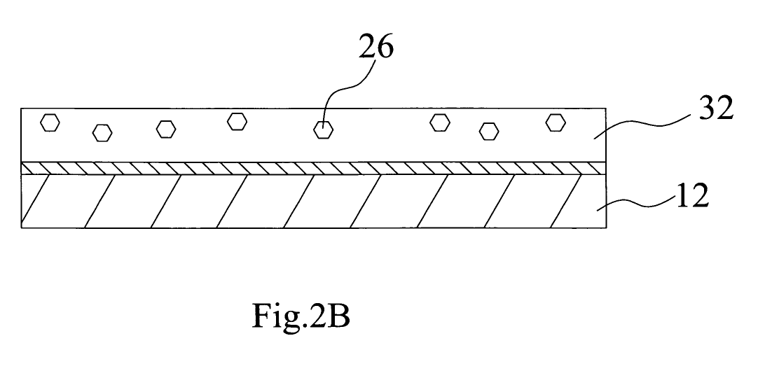

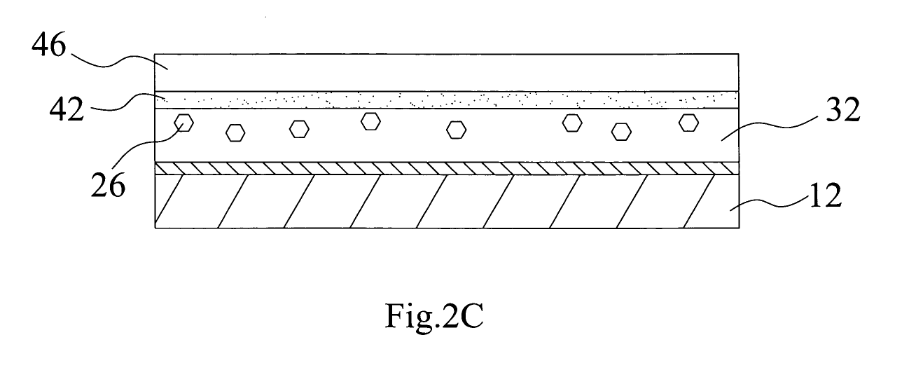

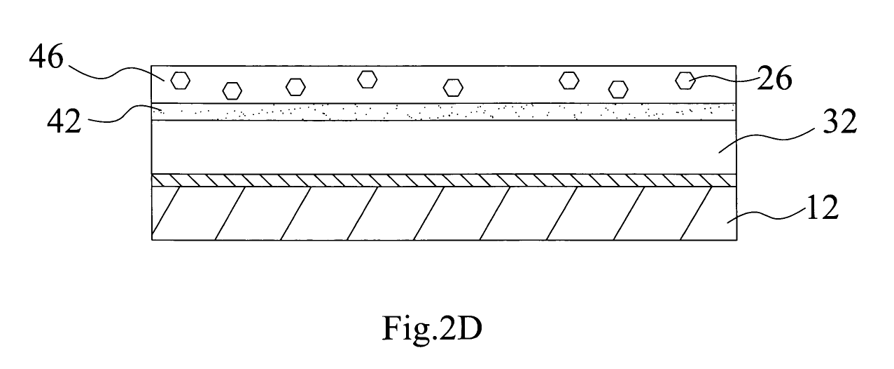

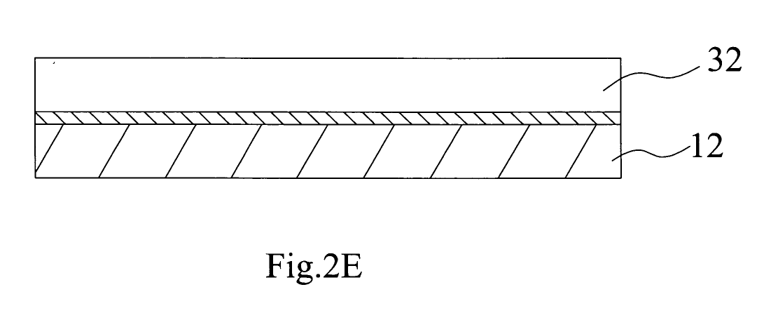

FIG. 2A to FIG. 2E are the cross-sectional diagrams illustrating the forming process of the poly-silicon semiconductor device. Referring to FIG. 2A, a substrate 12 made of any suitable material according to demand for semiconductor device is provided. For example, a glass substrate or a flexible substrate made of plastic is used for LCD, EL display and OLED, or a silicon wafer is used for CCD device. The silicon oxide or the silicon nitride is formed on the one surface of the substrate 12 as an insulated surface 13 by a low pressure chemical vapor deposition (LPCVD) process. An amorphous silicon layer 14 is formed on the insulated surface 13 and the material of the amorphous silicon layer 14 is silicon or silicon germanium compound. Next, the catalytic metal element 26, such as nickel (Ni), gold (Au), cobalt (Co), iron (Fe), palladium (Pd), platinum (Pt), copper (Cu), indium (In), silver (Ag) and titanium (Ti), are imposed on the surface of the amorphous silicon layer 14 by electron beam evaporation or spin-coating the metal ions solution with a coater. Referring to FIG. 2B, the catalytic metal element 26 is combined with the silicon in the amorphous silicon layer 14 to form a metal silicon compound to form a die along a particular direction and then convert to a poly-silicon layer 32 including the catalytic metal element 26. This method of utilizing the catalytic metal element 26 to form the poly-silicon layer 32 is called the Metal Induced Lateral Crystallization (MILC).

Furthermore, referring to FIG. 2C a compound, such as silicon nitride (Si₃N₂) and Tantalum (Ta) is formed on the upper surface of the poly-silicon layer 32 as a diffusion layer 42, so that the reaction of the diffusion layer 42 and the silicon is an inactive reaction. The diffusion layer 42 provides a good interface between the poly-silicon layer 32 and a gettering material layer 46 which will be formed later, and provides a protection of the poly-silicon layer 32 in the follow-up process. A new amorphous silicon layer or a metal layer is formed by electron beam evaporation or direct current sputtering on the upper surface of the diffusion layer 42 as a gettering material layer 46, wherein the material of the metal layer is tantalum (Ta), copper (Cu), iron (Fe), aluminum (Al), or platinum (Pt). Then, the heating and thermal annealing processes are proceeded to make the catalytic metal element 26 remained in the poly-silicon layer move to the gettering material layer 46 which has no catalytic metal element 26 previously, due to the heat energy and the concentration gradient. After the thermal annealing process, referring to FIG. 2D, the catalytic metal element 26 remained in the poly-silicon layer 32 previously is driven to move to the gettering material layer 46. Then the diffusion layer 42 and the gettering material layer 46 are removed together by means of etching, and in this etching process, the diffusion layer 42 provides a protection of poly-silicon layer to avoid damaging the surface structure of the poly-silicon layer 32 during the etching process. After finishing the foregoing steps, please referring to FIG. 2E, a semiconductor with a poly-silicon layer 32 is formed on the substrate, and then the poly-silicon layer can be continuously processed to form the device with high carrier mobility such as thin film transistors.

To sum up, the present invention can be applied to many difference substrates without increasing manufacturing step and production cost to manufacture the poly-silicon layer with bigger crystal and remove residual metal element in the poly-silicon layer effectively. Furthermore the present invention simplifies the manufacturing processes and enhances reliability of the semiconductor device.

Although the present invention has been explained in relation to its preferred embodiment, it is to be understood that other modifications and variation can be made without departing the spirit and scope of the invention as hereafter claimed.

What is claimed is:

1. A manufacturing method of a semiconductor device, comprising:
providing a substrate with an insulated surface;
forming an amorphous silicon layer on the insulated surface;
imposing a catalytic metal element on the amorphous silicon layer;
heating and catalyzing the amorphous silicon layer to form a poly-silicon layer;
forming a diffusion layer and a gettering material layer on the poly-silicon layer in order;
proceeding an annealing process on the gettering material layer and the poly-silicon layer; and
removing the diffusion layer and the gettering material layer after the annealing process.

2. A manufacturing method of a semiconductor device according to claim 1, wherein the insulated surface is provided by a silicon oxide layer.

3. A manufacturing method of a semiconductor device according to claim 1, wherein a material of the amorphous silicon layer is silicon or silicon germanium compound.

4. A manufacturing method of a semiconductor device according to claim 1, wherein a material of the substrate is glass, plastic or silicon-wafer.

5. A manufacturing method of a semiconductor device according to claim 1, wherein the catalytic metal element combines with a silicon in the amorphous silicon layer to form a metal silicon compound.

6. A manufacturing method of a semiconductor device according to claim 5, wherein the metal silicon compound induces the amorphous silicon layer to form a die along a particular direction and convert to the poly-silicon layer.

7. A manufacturing method of a semiconductor device according to claim 1, wherein a reaction of the diffusion layer and silicon is an inactive reaction.

8. A manufacturing method of a semiconductor device according to claim 7, wherein a material of the diffusion layer is silicon nitride.

9. A manufacturing method of a semiconductor device according to claim 1, wherein the gettering material layer is a metal layer or an amorphous silicon layer.

10. A manufacturing method of a semiconductor device according to claim 9, wherein a material of the metal layer is tantalum, copper, iron, aluminum, or platinum.

11. A manufacturing method of a semiconductor device according to claim 9, wherein a concentration of the catalytic metal element in the poly-silicon layer is higher than a concentration of the catalytic metal element in the gettering material layer before proceeding the annealing process.

12. A manufacturing method of a semiconductor device according to claim 9, wherein a concentration of the catalytic metal element in the gettering material layer is higher than a concentration of the catalytic metal element in the poly-silicon layer after proceeding the annealing process.

13. A manufacturing method of a semiconductor device according to claim 9, wherein forming the gettering material layer is electron beam evaporation or direct current sputtering.

14. A manufacturing method of a semiconductor device according to claim 1, wherein forming the catalytic metal element is electron beam evaporation or direct current sputtering.

15. A manufacturing method of a semiconductor device according to claim 1, wherein forming the catalytic metal element is spin-coating metal ions solution with a coater.

16. A manufacturing method of a semiconductor device according to claim 1, wherein the poly-silicon layer is continuously processed to form thin film transistors device after removing the diffusion layer and the gettering material layer.

17. A semiconductor device, comprising:
a substrate with an insulated surface;
a poly-silicon layer on the insulated surface, wherein the poly-silicon layer includes a catalytic metal element;
a diffusion layer on the poly-silicon layer; and
a gettering material layer on the diffusion layer, wherein a concentration of the catalytic metal element in the gettering material layer is higher than a concentration of the catalytic metal element in the poly-silicon layer.

18. A semiconductor device according to claim 17, wherein a material of the substrate is glass, plastic or silicon-wafer.

19. A semiconductor device according to claim 17, wherein a material of the amorphous silicon layer is silicon or silicon germanium compound.

20. A semiconductor device according to claim 17, wherein the catalytic metal element is selected from the group consisted of nickel, cobalt, iron, palladium, platinum, copper, gold, indium, silver and titanium.

21. A semiconductor device according to claim 17, wherein the gettering material layer is a metal layer or an amorphous silicon layer.

22. A semiconductor device according to claim 21, wherein a material of the metal layer is tantalum, copper, iron, aluminum, or platinum.
